(19) United States
(12) Patent Application Publication
(10) Pub. No.: US 2026/0113012 A1
(43) Pub. Date: Apr. 23, 2026

(54) ACOUSTIC WAVE DEVICE WITH ENHANCED QUALITY FACTOR AND FABRICATION METHOD THEREOF

(71) Applicant: RichWave Technology Corp., Taipei City (TW)

(72) Inventor: Hao-Min Huang, Taipei City (TW)

(73) Assignee: RichWave Technology Corp., Taipei City (TW)

(21) Appl. No.: 18/946,769

(22) Filed: Nov. 13, 2024

(30) Foreign Application Priority Data
Oct. 18, 2024 (TW) 113139718

(51) Int. Cl. H03H 3/02; H03H 9/02

(52) U.S. Cl. CPC H03H 3/02; H03H 9/02118

(57) ABSTRACT

A method of fabricating an acoustic wave device includes providing a first substrate, the first substrate comprising a first bulkplate and a first frame, and further comprising a first electrode, a piezoelectric layer, and a second electrode stacked in sequence. The first frame is disposed on the first bulkplate and at least partially surrounds the first electrode. The first substrate is thinned such that the first electrode is exposed from a first surface of the first substrate. A second substrate comprises a second bulkplate and a recess, and the recess is recessed from a second surface of the second substrate. The first surface of the first substrate and the second surface of the second substrate are bonded together, and the recess, the first electrode, the piezoelectric layer, and the second electrode at least partially overlap when viewed along a vertical direction to form an overlapping area.

### TECHNICAL FIELD

The invention relates to acoustic wave technology, and in particular, to an acoustic wave device with a weakened spurious mode and a method of fabricating the same.

### BACKGROUND

Bulk acoustic waves (BAW) devices may be used to convert and transmit electrical signals and/or acoustic signals. A BAW device may be widely used for communications, global positioning system (GPS), and military uses. A BAW device may be used as a filter to filter out noises from wireless signals so as to achieve a desired band of frequency and result in advantages such as lower transmission loss, stronger ability to avoid interference from electromagnetic, and/or a compact size. In addition, a BAW device may also be implemented in a resonator. A BAW device may generate a spurious mode, which may cause undesirable energy leakage and performance degradation.

### SUMMARY

According to an embodiment of the invention, a method of fabricating an acoustic wave device includes providing a first substrate. The first substrate includes a first bulkplate, a first frame, and further includes a first electrode, a piezoelectric layer, and a second electrode stacked in sequence. The first frame is disposed on the first bulkplate and at least partially surrounds the first electrode. The method further includes thinning the first substrate such that the first electrode is exposed from a first surface of the first substrate, and providing a second substrate. The second substrate includes a second bulkplate and a recess recessed from a second surface of the second substrate. The first surface of the first substrate and the second surface of the second substrate are bonded together, such that the recess, the first electrode, the piezoelectric layer, and the second electrode at least partially overlap when viewed along a vertical direction to form an overlapping area.

According to another embodiment of the invention, an acoustic wave device includes a first substrate and a second substrate. The first substrate includes a first surface, a first bulkplate, a first electrode, a piezoelectric layer, a second electrode, and a first frame. The first electrode, the piezoelectric layer, and the second electrode are stacked in sequence, and the first electrode is exposed from the first surface. The first frame is disposed in the first bulkplate and at least partially surrounds the first electrode. The second substrate includes a second surface, a second bulkplate, and a recess. The recess is disposed in the second bulkplate and recessed from the second surface. The first surface of the first substrate and the second surface of the second substrate are bonded together. The recess, the first electrode, the piezoelectric layer, and the second electrode at least partially overlap when viewed along a vertical direction. The first substrate and the second substrate form a sealed cavity at the recess.

According to another embodiment of the invention, a method of fabricating an acoustic wave device includes providing a first bulkplate, forming a first electrode on the first bulkplate, and forming a first frame on the first bulkplate. The first frame at least partially surrounds the first electrode and is separated from the first electrode. The method further includes forming a piezoelectric layer at least on the first electrode, forming a second electrode at least on the piezoelectric layer, forming a contact hole penetrating the piezoelectric layer, and forming a first contact in the contact hole. The first contact is electrically connected to the first electrode. The method further includes forming a passivation layer to at least cover the second electrode, so as to form a first substrate. The method further includes applying an adhesion layer to a first side of the first substrate, attaching the first substrate to a carrier via the adhesion layer, and performing a planarization process from a second side of the first substrate to reduce a thickness of the first substrate to the first surface, such that the first electrode is exposed from the first surface. The method further includes providing a second substrate and the second substrate includes a second bulkplate and a recess recessed from a second surface of the second substrate. The method further includes bonding the first surface of the first substrate and the second surface of the second substrate together, and removing the carrier and the adhesion layer. When viewed along a vertical direction, the recess, the first electrode, the piezoelectric layer, and the second electrode at least partially overlap to form an overlapping area.

According to another embodiment of the invention, an acoustic wave device includes a first substrate and a second substrate. The first substrate includes a first surface, a first electrode, a piezoelectric layer, a second electrode, and a first frame. The first electrode, the piezoelectric layer, and the second electrode are stacked in sequence, and the first electrode is exposed from the first surface. The first frame at least partially surrounds the first electrode. The second substrate includes a second surface, a second bulkplate, a recess, and a second frame. The recess is disposed in the second bulkplate and recessed from the second surface. The second frame is disposed in the second bulkplate. The first surface of the first substrate and the second surface of the second substrate are bonded together. The recess, the first electrode, the piezoelectric layer, and the second electrode at least partially overlap when viewed along a vertical direction. The first substrate and the second substrate form a sealed cavity at the recess. The second frame at least partially surrounds the sealed cavity.

### BRIEF DESCRIPTION OF THE DRAWINGS

FIG. 1A is a cross sectional view of an acoustic wave device according to an embodiment of the invention.

FIG. 1B is a top view of an acoustic wave device according to an embodiment of the invention.

FIG. 2 is a flowchart of a method of fabricating the acoustic wave device according to an embodiment of the invention.

FIGS. 3A to 3C and FIGS. 4 to 6 show exemplary steps of a method of fabricating an acoustic wave device according to an embodiment of the invention.

FIG. 7 is a cross sectional view of an acoustic wave device according to another embodiment of the invention.

FIG. 8 is a cross sectional view of an acoustic wave device according to another embodiment of the invention.

FIG. 9 is a flowchart of a method of fabricating the acoustic wave device according to another embodiment of the invention.

FIGS. 10 to 12 show exemplary steps of a method of fabricating an acoustic wave device according to another embodiment of the invention.

FIG. 13 is a cross sectional view of an acoustic wave device according to another embodiment of the invention.

### DETAILED DESCRIPTION

Below, exemplary embodiments will be described in detail with reference to accompanying drawings so as to be easily realized by a person having ordinary knowledge in the art. The inventive concept may be embodied in various forms without being limited to the exemplary embodiments set forth herein. Descriptions of well-known parts may be omitted for clarity, and like reference numerals refer to like elements throughout.

As used herein, the terms ‘upper,’ ‘lower,’ ‘left,’ and ‘right’ are intended for illustrative purposes only and do not limit the structure or method in the embodiments. Further, these terms may have different meanings in various embodiments. In the embodiments, certain features, components, structures, materials, and configurations are described merely as illustrative and not restrictive. For example, elements in one embodiment may be omitted or applied differently in another embodiment.

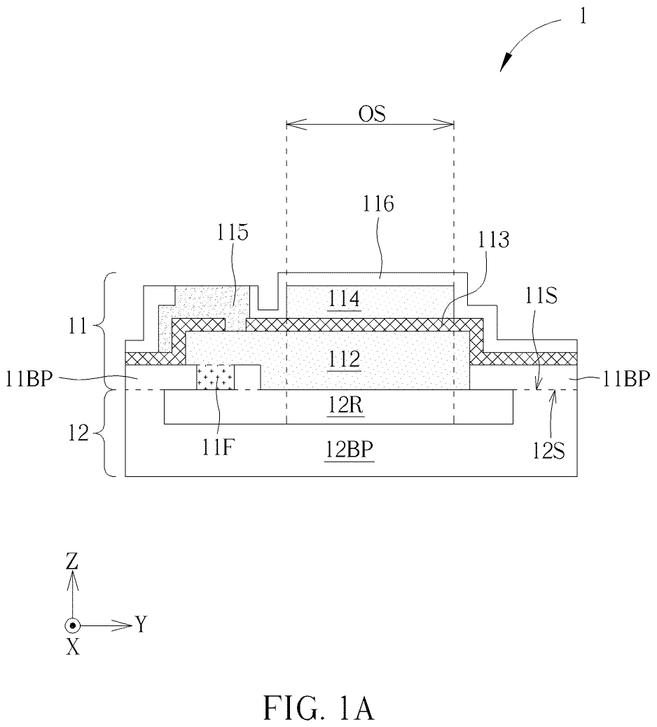

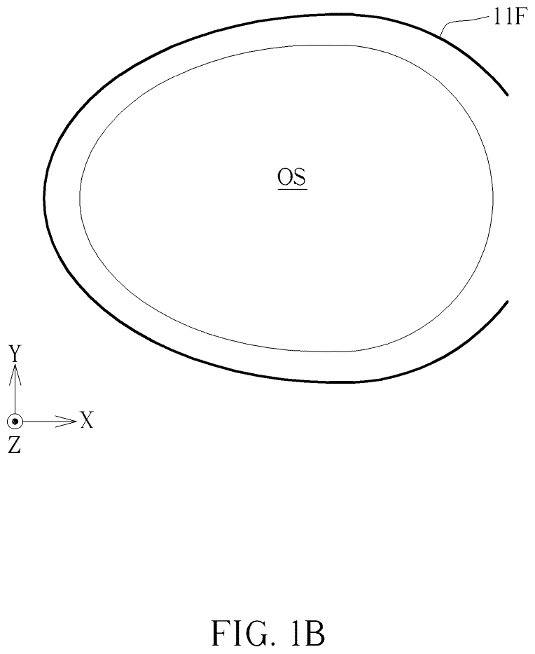

FIG. 1A is a cross sectional view of an acoustic wave device 1 according to an embodiment of the invention.

In some embodiments, an acoustic wave device 1 may include a bulk acoustic waves (BAW) device, and may be used in a resonator, a filter or other applications. In some embodiments, the acoustic wave device 1 may serve as a BAW resonator, receiving an input signal to generate a standing acoustic wave, and then converting the standing acoustic wave into a resonance signal. In other embodiments, the acoustic wave device 1 may serve as a BAW filter, receiving an input signal from e.g., an antenna, and filtering the received signal based on a frequency selectivity to allow signals of desired frequencies to pass. Various embodiments of the acoustic wave device 1 are provided herein to describe exemplary applications, which may not limit the uses of the acoustic wave device 1. For example, a bulk acoustic wave device may include a thin film bulk acoustic resonator (FBAR).

In some embodiments, the acoustic wave device 1 may include a first substrate 11 and a second substrate 12. The first substrate 11 may include a first bulkplate 11BP and a first frame 11F disposed in the first bulkplate 11BP. The first substrate 11 may further include a first electrode 112, a piezoelectric layer 113, and a second electrode 114 stacked in sequence. The first electrode 112 may be exposed from a surface (e.g., the first surface 11S) of the first substrate 11, and the first frame 11F may at least partially surround the first electrode 112. For example, the first frame 11F may be disposed near the peripheral region of the first electrode 112.

Additionally, the second substrate 12 may include a second bulkplate 12BP and a recess 12R formed in the second bulkplate 12BP, with the recess 12R recessed from a surface (e.g., the second surface 12S) of the second substrate 12. As shown in FIG. 1A, the first surface 11S of the first substrate 11 may be bonded to the second surface 12S of the second substrate 12, such that when viewed along a vertical direction (e.g., the Z direction perpendicular to the first surface 11S), the recess 12R, the first electrode 112, the piezoelectric layer 113, and the second electrode 114 at least partially overlap to form an overlapping area OS. After bonding, the first substrate 11 and the second substrate 12 may form a cavity at the recess 12R. For example, the cavity may be a sealed or enclosed cavity. The cavity may be used as a reflector for acoustic waves, to reduce acoustic wave leakage along the vertical direction.

In some embodiments, the materials of the first bulkplate 11BP and the second bulkplate 12BP may be the same or different.

In some embodiments, the first substrate 11 may further include a first contact 115 and a passivation layer 116. The first contact 115 may be electrically connected to the first electrode 112, and the passivation layer 116 may at least cover the second electrode 114, as described further below. In other embodiments, the first substrate 11 may further include a second contact (not shown) that is electrically connected to the second electrode 114. In some embodiments, the material of the second electrode 114 may be the same as or different from the material of the first electrode 112.

In some embodiments, the materials of the first bulkplate 11BP and/or the second bulkplate 12BP may include silicon, glass, ceramic, gallium arsenide, and/or silicon carbide. The materials of the first electrode 112 and/or the second electrode 114 may include conductive materials such as molybdenum (Mo), copper (Cu), aluminum (Al), gold (Au), platinum (Pt), tungsten (W), other suitable metals. or a combination thereof. The material of the piezoelectric layer 113 may include, for example, at least one of the followings: zinc oxide (ZnO), aluminum nitride (AlN), lithium niobate (LiTaO3, LT), lithium niobate (LN), quartz (QZ), titanate Lead (PTO), lead zirconate titanate (PZT) and other materials or a combination thereof. In some embodiments, the piezoelectric layer 113 may be doped with a rare earth element such as scandium (Sc). The materials of the first contact 115 and/or the second contact may include conductive materials such as molybdenum (Mo), copper (Cu), aluminum (Al), gold (Au), platinum (Pt), tungsten (W), other suitable metals or a combination thereof. The material of the passivation layer 116 may include silicon dioxide (SiO2), silicon nitride (SiN), or other suitable materials. The above materials are merely examples and are not intended to limit the scope of the present invention.

In some embodiments, during the operation, the second electrode 114 may receive an input signal via the second contact and the first electrode 112 may be grounded via the first contact 115 so as to generate an acoustic wave propagating along a vertical direction Z. The piezoelectric layer 113 may convert the acoustic wave into a resonant signal with a resonant frequency. The resonant frequency of the acoustic wave device 1 may be determined by various parameters, including but is not limited to the selected material and thickness of the piezoelectric layer 113, as well as the dimensions and thickness of the first electrode 112 and/or the second electrode 114, among other factors. For example, the resonant frequency may range from 100 megahertz (MHz) to 20 gigahertz (GHz).

In related art, in order to form a cavity in an acoustic wave device, a sacrificial material may be used to fill a designated space, and a through hole may subsequently be drilled to access the sacrificial material. The sacrificial material may be removed through the through hole, so as to form a cavity. However, forming the through hole in either a first substrate or a second substrate may increase the process complexity and/or weaken the structural of the acoustic wave device, and thus this approach is not ideal for optimizing the performance of the acoustic wave device. In some embodiments, when forming the acoustic wave device 1, a through hole may not be required. Therefore, the first substrate 11 or the second substrate 12 may be processed without drilling, and thus the fabrication process may be simplified and the structure of the acoustic wave device 1 may be strengthened.

FIG. 1B is a top view of an acoustic wave device according to an embodiment of the invention. In some embodiments, the overlapping area OS may be referred to as an active area, and the acoustic waves may propagate along a vertical direction Z in the active area. The first frame 11F may further be disposed near the peripheral region of the overlapping area OS. In some embodiments, the first frame 11F may at least partially surround the overlapping area OS.

In some embodiments, as shown in FIG. 1B, the outline of the overlapping area OS may be, but is not limited to, egg-shaped. In other embodiments, the outline of the overlapping area OS may be other shapes such as a truncated egg shape, a square, a circle, a pentagon, or other regular or irregular shapes. The first frame 11F may be disposed to substantially continuously surround the overlapping area OS, for example, surrounding more than 50% of the circumference of the overlapping area OS. For example, the first frame 11F may continuously surround the narrow end and side portions of an egg-shaped overlapping area OS, with an opening at the wide end, thus partially surrounding the overlapping area OS. In other embodiments, the opening of the first frame 11F may be positioned differently and vary in size. For instance, the opening may be positioned at the narrow end or at the side portions of the egg-shaped overlapping area OS. In another embodiment, the first frame 11F may continuously and completely encircle the entire overlapping area OS.

In other embodiments, the first frame 11F may be configured to substantially and discontinuously surround the overlapping area OS. For example, the first frame 11F may be segmented, including multiple discontinuous segments located near the peripheral region of the overlapping area OS. In other words, the outline of the first frame 11F may feature multiple openings, such as three openings. For example, a first opening may be located near the narrow end of the overlapping area OS, a second opening may be located near a side portion of the overlapping area OS, and a third opening may be located near the wide end of the overlapping area OS. In the above embodiments, the described shape is merely for illustrative purposes and not intended to limit the scope of the present invention.

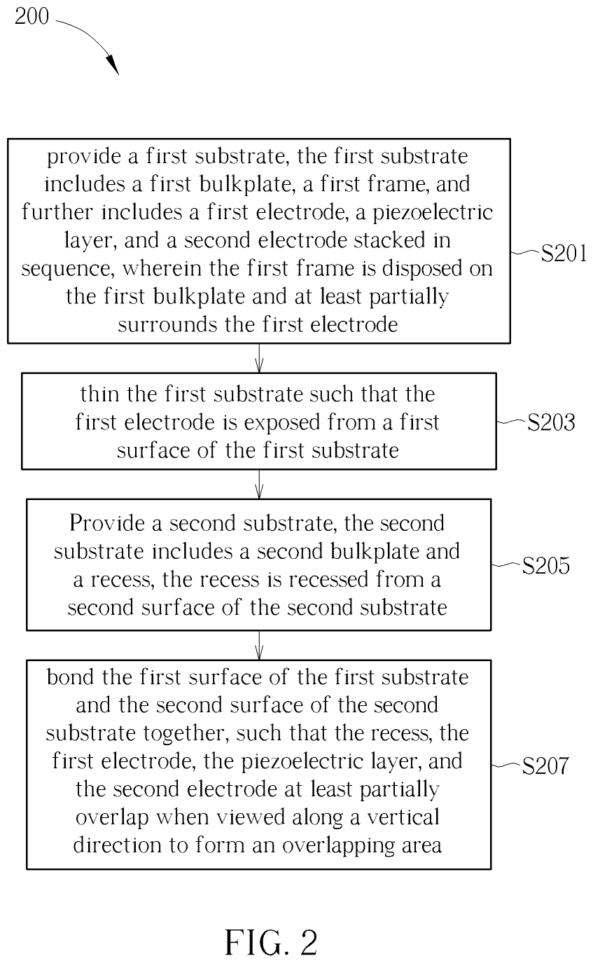

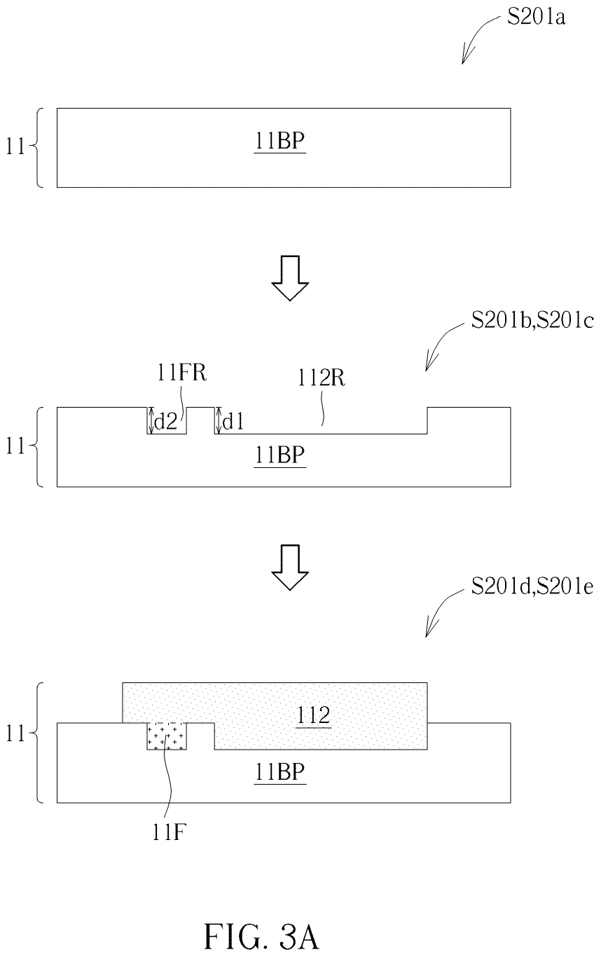

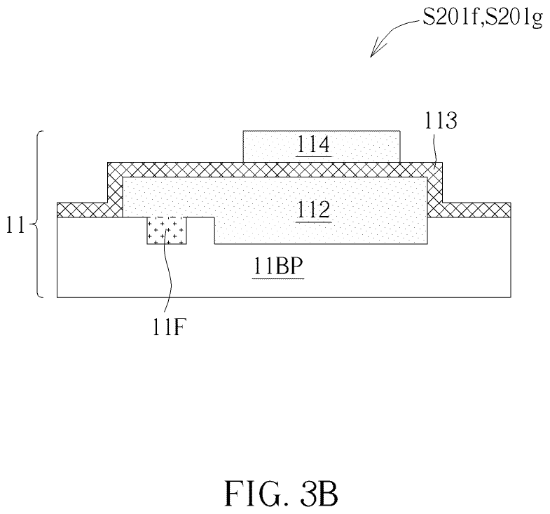

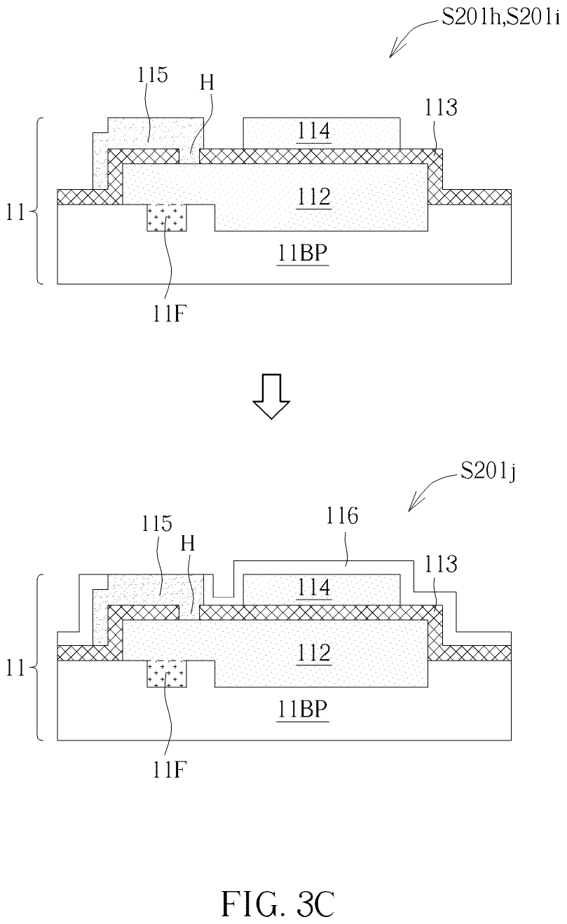

FIG. 2 is a flowchart of a method 200 of fabricating the acoustic wave device according to an embodiment of the invention. FIGS. 3A to 3C and FIGS. 4 to 6 show exemplary steps of a method 200 of fabricating an acoustic wave device according to an embodiment of the present invention. An exemplary embodiment of the method 200 is discussed below with reference to FIGS. 1A, 2, 3A to 3C, and 4 to 6.

In some embodiments, the method 200 may include Steps S201 to S207. Any reasonable step change or adjustment is within the scope of the disclosure. Steps S201 to S207 are exemplified as follows:
Step S201: Provide a first substrate 11 which includes a first bulkplate 11BP, a first frame 11F, and sequentially stacked a first electrode 112, a piezoelectric layer 113, and a second electrode 114. The first frame 11F is disposed in the first bulkplate 11BP and at least partially surrounds the first electrode 112.
Step S203: Thin the first substrate 11 such that the first electrode 112 is exposed from the first surface 11S of the first substrate 11;
Step S205: Provide a second substrate 12 which includes a second bulkplate 12BP and a recess 12R recessed from the second surface 12S of the second substrate 12;
Step S207: Bond the first surface 11S of the first substrate 11 and the second surface 12S of the second substrate 12 together, such that when viewed along a vertical direction, the recess 12R, the first electrode 112, the piezoelectric layer 113, and the second electrode 114 at least partially overlap to form an overlapping area OS.

In some embodiments, Step S201 may include Steps S201a to S201j to provide the first substrate 11, as illustrated in FIGS. 3A to 3C.

In Step S201a, the first bulkplate 11BP is provided. In Step S201b, a first electrode recess 112R is formed in the first bulkplate 11BP and the first electrode recess 112R may be subsequently used to accommodate the first electrode 112. In Step S201c, a first frame recess 11FR is formed in the first bulkplate 11BP. The first frame recess 11FR is separated from the first electrode recess 112R, and may be subsequently used to form the first frame 11F. Additionally, the first frame recess 11FR may disposed near the peripheral region of the first electrode recess 112R, thereby at least partially surrounding the first electrode recess 112R. In some embodiments, Step S201b and Step S201c may be executed simultaneously, or the sequence may be reversed. For example, the step of forming the first electrode recess 112R and/or the first frame recess 11FR may involve a dry etching and/or a wet etching. As illustrated in FIG. 3A, the first electrode recess 112R may have a depth d1, the first frame recess 11FR may have a depth d2, and the depth d2 may be equal to or less than the depth d1.

In Step S201d, the first electrode 112 is formed in the first electrode recess 112R. For example, forming the first electrode 112 may involve depositing a conductive layer (e.g., molybdenum (Mo)) on the first substrate 11 and then patterning the conductive layer to form the first electrode 112. In Step S201e, the first frame 11F is formed by utilizing the first frame recess 11FR. For example, the first frame recess 11FR may be filled with a conductive material (e.g., molybdenum (Mo) or tungsten (W)) or a dielectric material (e.g., SiO₂) so as to form the first frame 11F. The material used to form the first frame 11F may be the same as or different from the material used to form the first electrode 112. If the same material is used, the first electrode 112 and the first frame 11F may be formed in a single step. If different materials are used, the first electrode 112 and the first frame 11F may be formed in separate steps. In other words, Step S201d and Step S201e may be executed simultaneously, or the sequence may be reversed. In some embodiments, the first frame 11F may be the first frame recess 11FR itself without any filling material. That is, in the above Step S201e, no material is used to fill the first frame recess 11FR.

In some embodiments, the material for the first frame 11F may be selected to have a higher density than the first electrode 112, so as to reduce or prevent a leakage of acoustic waves in horizontal direction (e.g., along X/Y directions parallel to the first surface 11S), thereby suppressing a spurious mode. The density of a material may be defined as the mass per unit volume. For example, the density of aluminum is about 2.9 g/cm³, the density of molybdenum is about 10.2 g/cm³, and the density of tungsten is about 19.25 g/cm³.

In some embodiments, Step S201 may further include Steps S201f to S201j to provide the first substrate 11, as illustrated in FIGS. 3B and 3C. In Step S201f, a piezoelectric layer 113 is formed on the first electrode 112 such that the piezoelectric layer 113 is at least partially disposed on the first electrode 112. In Step S201g, the second electrode 114 is formed on the piezoelectric layer 113 such that the second electrode 114 is at least partially disposed on the piezoelectric layer 113. In Step S201h, a contact hole H is formed to penetrate the piezoelectric layer 113. In Step S201i, a first contact 115 is formed in the contact hole H and electrically connected to the first electrode 112. Specifically, the first contact 115 fills the contact hole H to contact the first electrode 112. In Step S201j, a passivation layer 116 is formed to protect the surface of the acoustic wave device. The passivation layer 116 may at least cover the second electrode 114 and may expose the first contact 115.

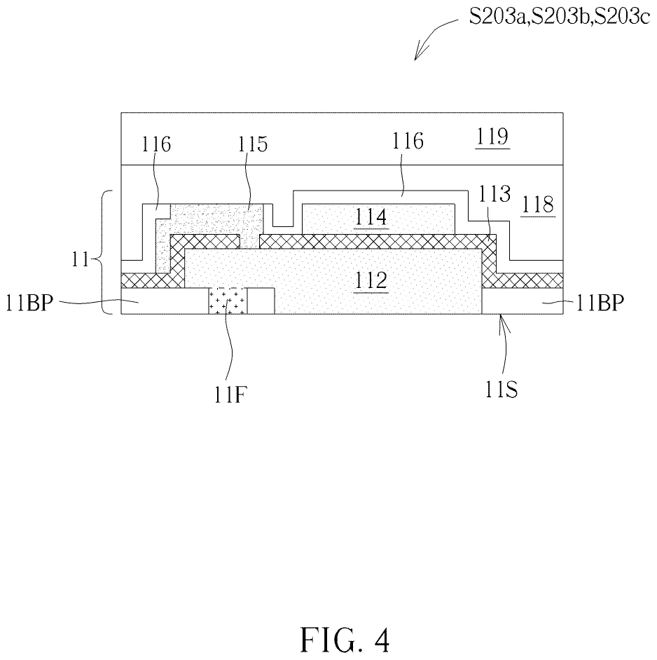

In some embodiments, Step S203 may include Steps S203a to S203c to thin the first substrate 11, as illustrated in FIG. 4.

In Step S203a, an adhesion layer 118 is applied to the first side of the first substrate 11 (as shown in FIG. 4). In Step S203b, the first substrate 11 is attached to the carrier 119 by using the adhesion layer 118. In Step S203c, a planarization process from the second side (the lower side in FIG. 4) is performed to reduce the thickness of the first substrate 11 to the first surface 11S. In some embodiments, the planarization process may involve a chemical mechanical polishing and/or smart cutting. Smart cutting, for example, may involve using an ion implantation and a wafer bonding to precisely cut semiconductor substrates.

In the embodiment, the first substrate 11 is thinned to the first surface 11S to expose the first electrode 112. Further, during this step, the first frame 11F may or may not be exposed from the first surface 11S. For example, referring to FIG. 3A, in case that the depth d2 of the first frame recess 11FR is less than the depth d1 of the first electrode recess 112R, the first frame 11F is not exposed from the first surface 11S.

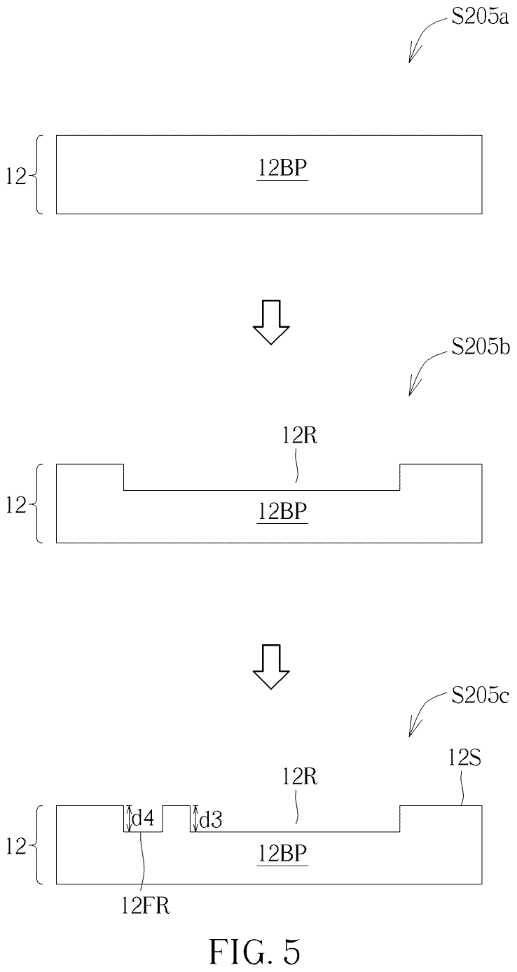

In some embodiments, Step S205 may include Steps S205a to S205c to provide the second substrate 12, as illustrated in FIG. 5.

In Step S205a, the second bulkplate 12BP is provided. In Step S205b, the recess 12R is formed in the second bulkplate 12BP. In other embodiments, Step S205 of providing the second substrate 12 may further include Step S205c, where a second frame recess 12FR is formed in the second bulkplate 12BP and is separated from the recess 12R. Additionally, the second frame recess 12FR may be disposed near the peripheral region of the recess 12R, so as to at least partially surround the recess 12R. Specifically, the recess 12R and/or the second frame recess 12FR may be recessed from the second surface 12S of the second substrate 12. In some embodiments, Steps S205b and S205c may be executed simultaneously, or the sequence may be reversed. In some embodiments, the step of forming the recess 12R and/or the second frame recess 12FR may involve a dry etching and/or a wet etching process. Further shown in FIG. 5, the recess 12R may have a depth d3, the second frame recess 12FR may have a depth d4, and the depth d4 may be less than, equal to, or greater than the depth d3.

In some embodiments, Step S205 of providing the second substrate 12 may further include filling the second frame recess 12FR with a conductive or dielectric material to form the second frame 12F, and the details will be further discussed below. In some embodiments, Step S201 of providing the first substrate 11 and Step S205 of providing the second substrate 12 may be executed simultaneously, or the sequence may be reversed.

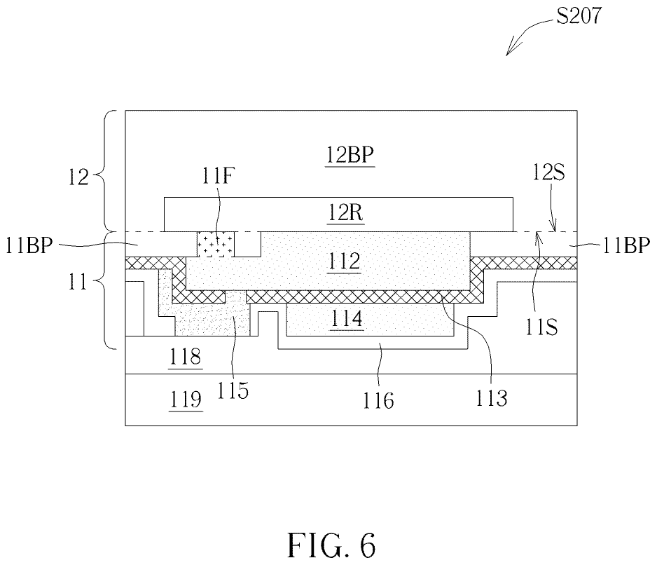

In some embodiments as shown in FIG. 6, Step S207 may involve bonding the first surface 11S of the first substrate 11 and the second surface 12S of the second substrate 12 together. Further, Step S207 may involve flipping the first substrate 11 or the second substrate 12 such that the second surface 12S of the second substrate 12 and the first surface 11S of the first substrate 11 are bonded, followed by removing the carrier 119 and/or the adhesion layer 118. After the bonding in Step S207, the first substrate 11 and the second substrate 12 may form a sealed cavity at the recess 12R, and the sealed cavity may serve as a reflector for the acoustic wave device. In some embodiments, the second substrate 12 and the first substrate 11 may be bonded by applying an adhesive and pressure to join the second surface 12S of the second substrate 12 and the first surface 11S of the first substrate 11. The larger the bonding surface between the first surface 11S of the first substrate 11 and the second surface 12S of the second substrate 12, the more stable the bonding between the first substrate 11 and the second substrate 12.

In the method 200, the second substrate 12 including the recess 12R is bonded to the first substrate 11 to form the sealed cavity. This bonding method eliminates the need for a through hole accessing the recess 12R in either the first substrate 11 or the second substrate 12, thereby enhancing the transmission efficiency of the acoustic wave device, reducing process complexity, and/or enhancing the structural strength of the acoustic wave device.

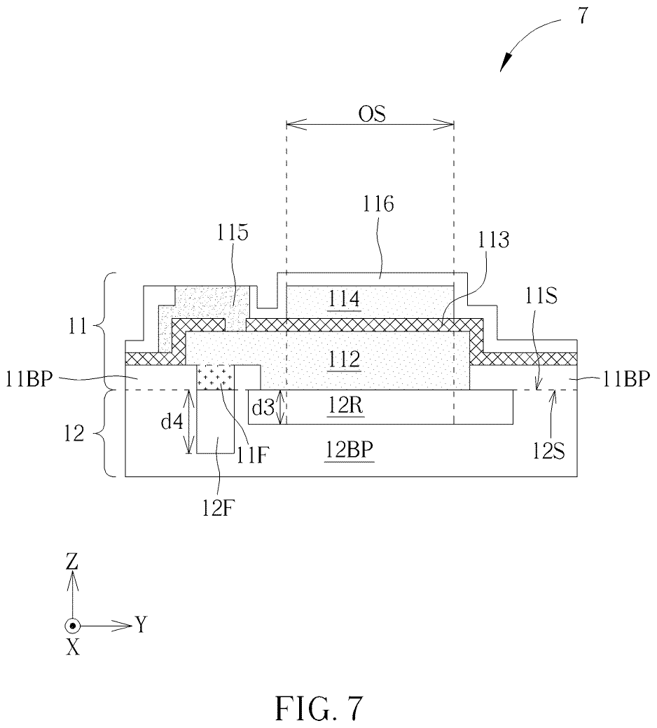

FIG. 7 is a cross sectional view of an acoustic wave device 7 according to another embodiment of the invention. The acoustic wave device 7 may be similar to the acoustic wave device 1 and the details may not be repeated. The difference between the acoustic wave devices 7 and 1 may be discussed as follows. The second substrate 12 of the acoustic wave device 7 may further include a second frame 12F. Refer to both FIG. 5 and FIG. 7, the second frame recess 12FR may be formed in the second bulkplate 12BP, and further the second frame recess 12FR may be optionally filled with a conductive material or a dielectric material to form the second frame 12F. After the bonding in Step S207, the second frame 12F near the peripheral region of the cavity may be formed by the second frame recess 12FR. In other words, the second frame 12F may at least partially surround the cavity and may be positioned in the second bulkplate 12BP.

In some embodiments, the first frame 11F and the second frame 12F may be at least partially aligned. As shown in FIG. 7, the first frame 11F and the second frame 12F may be fully aligned. In other embodiments, the first frame 11F and the second frame 12F may not be aligned.

In other embodiments, a plurality of stacked layers may be disposed in the recess 12R. The plurality of stacked layers may include at least a first layer having a first acoustic wave impedance, and a second layer having a second acoustic wave impedance and stacked on the first layer. The first acoustic impedance may be less than the second acoustic impedance. In the embodiment, the plurality of stacked layers may form a Bragg reflector, and the Bragg reflector may be used to reduce or prevent acoustic wave leakage along the vertical direction, thereby suppressing the spurious mode. Specifically, the first layer and the second layer of the plurality of stacked layers may be different material layers. Alternatively, the first layer and the second layer may include substantially the same material but include different dopants or dopant concentrations to achieve different refractive indexes for acoustic waves.

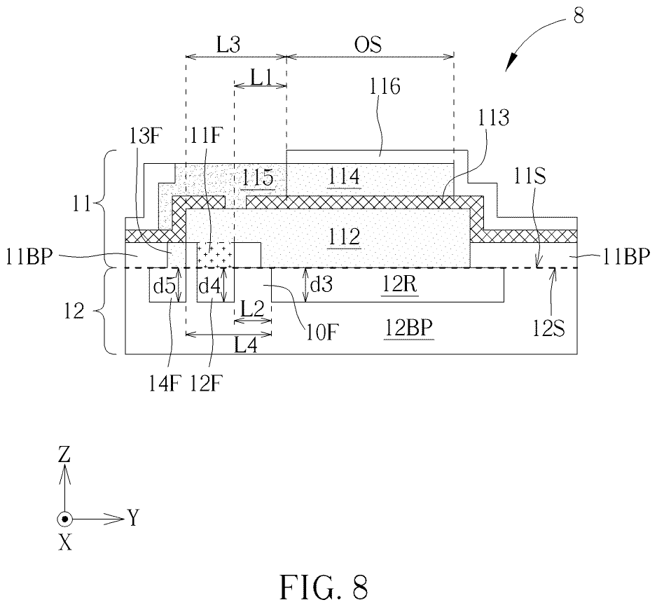

In another embodiment, both the first substrate 11 and the second substrate 12 may include a plurality of frames. FIG. 8 is a cross sectional view of an acoustic wave device 8 according to another embodiment of the invention. The acoustic wave device 8 may be similar to the acoustic wave device 1 and the details may not be repeated. The difference between the acoustic wave devices 8 and 1 may be discussed as follows.

In some embodiments, the first substrate 11 of the acoustic wave device 8 may further include a third frame 13F disposed in the first bulkplate 11BP and near the peripheral region of the first electrode 112. In some embodiments, a horizontal distance L3 between the third frame 13F and the overlapping area OS may be greater than a horizontal distance L1 between the first frame 11F and the overlapping area OS. In other words, with respect to the XY plane, the third frame 13F is positioned farther than the first frame 11F from the overlapping area OS.

In some embodiments, as shown in FIG. 8, the dimension of the third frame 13F along the direction Y (e.g., width) may be the same as or different from the dimension of the first frame 11F along the direction Y. Moreover, the dimension of the third frame 13F along the vertical direction Z (e.g., depth) may be the same as or different from the dimension of the first frame 11F along the vertical direction Z. The step of forming the third frame 13F may be similar to the step of forming the first frame 11F, and therefore will not be repeated here. In some embodiments, the filling material used for the third frame 13F (if applicable) may differ from the material used for the first frame 11F (if applicable). For example, the filling material for the third frame 13F may be a dielectric material, and the filling material for the first frame 11F may be a metal.

In some embodiments, the second substrate 12 of the acoustic wave device 8 may further include the fourth frame 14F disposed in the second bulkplate 12BP. In other words, the fourth frame 14F may be disposed near the peripheral region of the cavity formed by the recess 12R, and further be disposed near the peripheral region of the second frame 12F (if present). In other words, the fourth frame 14F may at least partially surround the cavity, and may further at least partially surround the second frame 12F (if present). For example, a horizontal distance L4 between the fourth frame 14F and the overlapping area OS may be greater than a horizontal distance L2 between the second frame 12F and the overlapping area OS. In other words, with respect to the XY plane, the fourth frame 14F is positioned farther than the second frame 12F from the overlapping area OS.

In some embodiments, as shown in FIG. 8, the dimension of the fourth frame 14F along the direction Y (e.g., width) may be the same as or different from the dimension of the second frame 12F along the direction Y. Moreover, the dimension of the fourth frame 14F along the vertical direction Z (e.g., depth) may be the same as or different from the dimension of the second frame 12F along the vertical direction Z. The step of forming the fourth frame 14F may resemble the step of forming the second frame 12F. For example, a fourth frame recess may be formed in the second bulkplate 12BP, and the fourth frame recess may be separated from the recess 12R, and further separated from the second frame recess 12FR. In a subsequent bonding step, a fourth frame 14F may be formed by using the fourth frame recess. The filling material used for the fourth frame 14F (if applicable) may be different from that used for the second frame 12F (if applicable).

In some embodiments, the depth d4 of the second frame 12F and/or the depth d5 of the fourth frame 14F may be the same as or different from the depth d3 of the recess 12R. For instance, the depth d5 of the fourth frame 14F may be larger than the depth d4 of the second frame 12F, and the depth d4 of the second frame 12F may be larger than the depth d3 of the recess 12R.

In the embodiment shown in FIG. 8, the horizontal distance is measured from the right edge of the frame (e.g., the right edge of the first frame 11F) to the left edge of the overlapping area OS. In other embodiments, the distance may be measured from the center axis of the frame to the center axis of the overlapping area OS.

In some embodiments, a plurality of frames may be formed as additional structures (e.g., additional reflective structures and/or mass load structures) near the peripheral region of the overlapping area OS (e.g., the active area), so as to further reduce or prevent the leakage of acoustic waves along the horizontal direction, thereby suppressing a spurious mode.

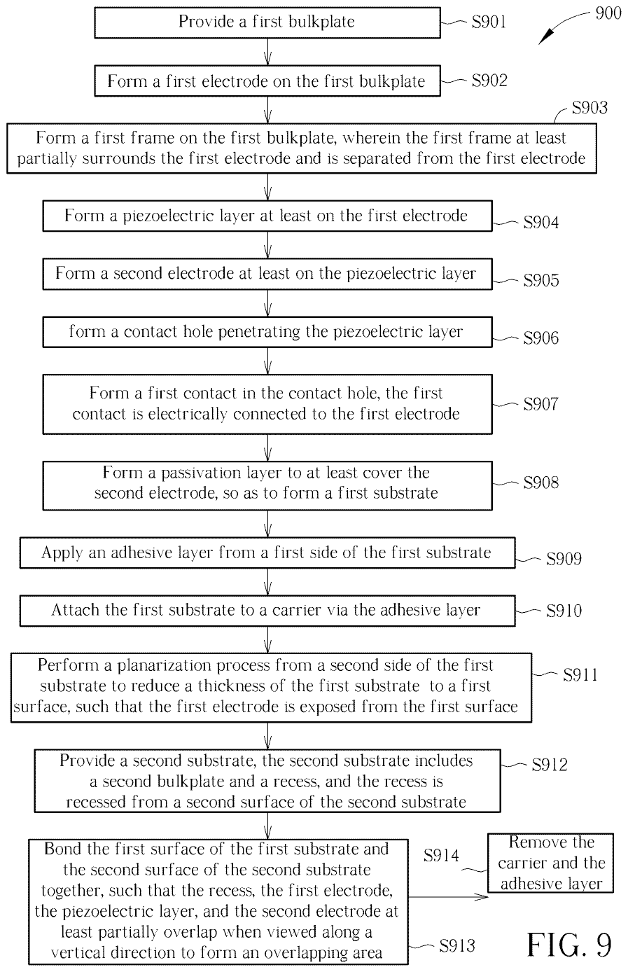

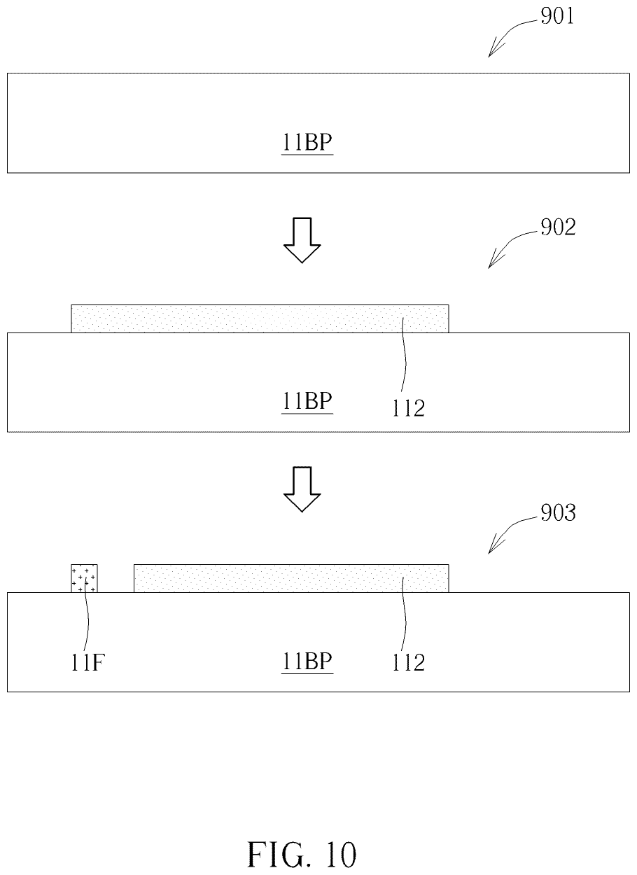

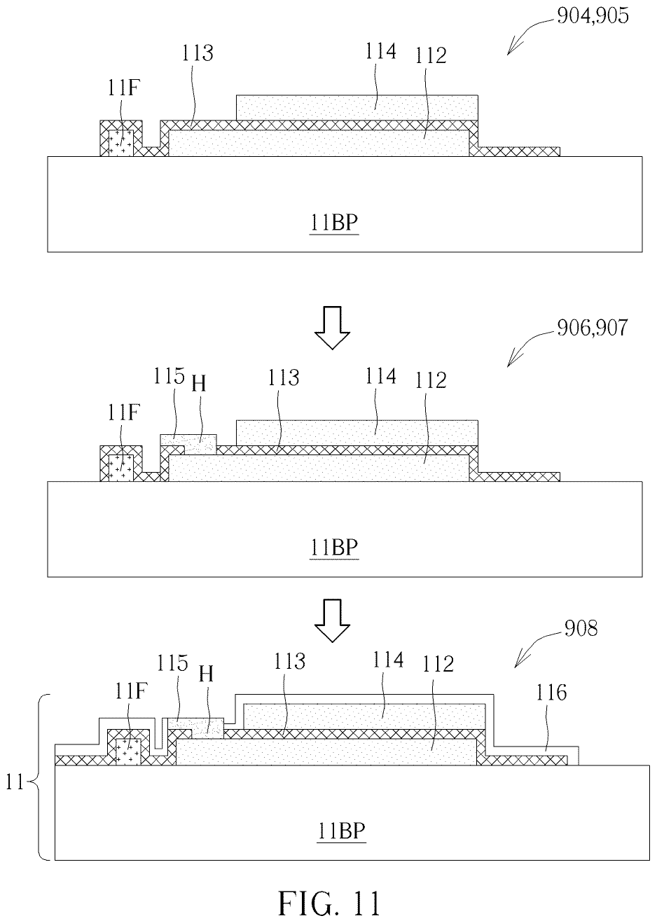

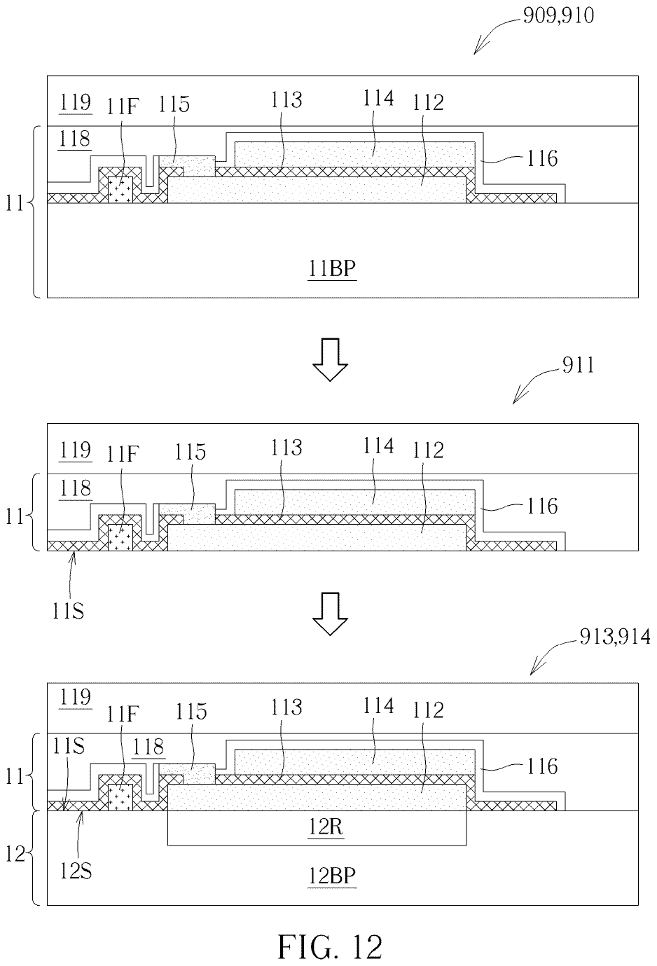

FIG. 9 is a flowchart of a method 900 of fabricating the acoustic wave device according to another embodiment of the invention. FIGS. 10 to 12 show exemplary steps of a method 900 of fabricating an acoustic wave device according to another embodiment of the present invention. An exemplary embodiment of the method 900 is now discussed with reference to FIGS. 9 to 12.

In some embodiments, the method 900 may include Steps S901 to S914. Any reasonable step change or adjustment is within the scope of the disclosure. Steps S901 to S914 are exemplified as follows:
Step 901: Provide a first bulkplate 11BP;
Step 902: Form a first electrode 112 on the first bulkplate 11BP;
Step 903: Form a first frame 11F on the first bulkplate 11BP, where the first frame 11F at least partially surrounds the first electrode 112 and is separated from the first electrode 112;
Step 904: Form a piezoelectric layer 113 at least on the first electrode 112;
Step 905: Form a second electrode 114 at least on the piezoelectric layer 113;
Step 906: Form a contact hole H penetrating the piezoelectric layer 113;
Step 907: Form a first contact 115 in the contact hole H, the first contact 115 being electrically connected to the first electrode 112;
Step 908: Form a passivation layer 116 which at least covers the second electrode 114, so as to form the first substrate 11;
Step 909: Apply the adhesion layer 118 to a first side of the first substrate 11;
Step 910: Attach the first substrate 11 to the carrier 119 via the adhesion layer 118;
Step 911: Perform a planarization process from a second side of the first substrate 11 to reduce the thickness of the first substrate 11 to a first surface 11S, such that the first electrode 112 is exposed from the first surface 11S;
Step 912: Provide a second substrate 12 including a second bulkplate 12BP and a recess 12R, the recess 12R being recessed from the second surface 12S of the second substrate 12;
Step 913: Bond the first surface 11S of the first substrate 11 and the second surface 12S of the second substrate 12 together, such that when viewed along a vertical direction, the recess 12R, the first electrode 112, the piezoelectric layer 113, and the second electrode 114 at least partially overlap to form an overlapping area; and
Step 914: Remove the carrier 119 and/or the adhesion layer 118.

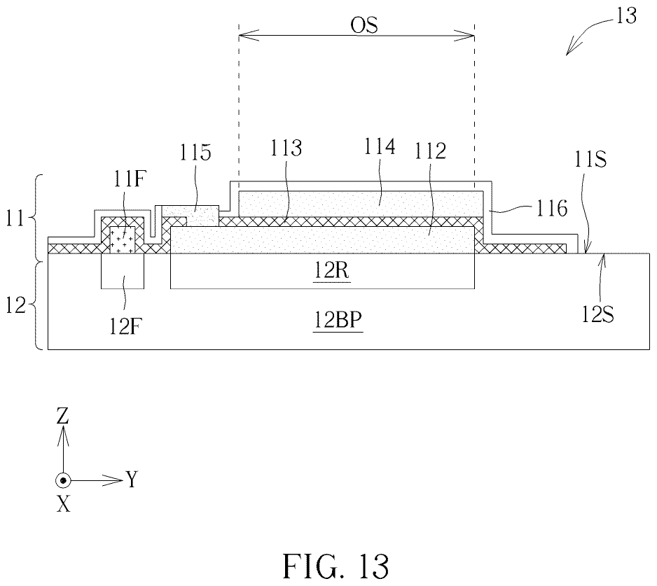

FIG. 13 is a cross sectional view of an acoustic wave device 13 according to another embodiment of the invention. The acoustic wave device 13 may be fabricated by the method 900 shown in FIG. 9. In some embodiments, the acoustic wave device 13 may include a first substrate 11. The first substrate 11 includes a first frame 11F, a first electrode 112, a piezoelectric layer 113, and a second electrode 114. The first electrode 112, piezoelectric layer 113, and second electrode 114 are stacked sequentially. The first electrode 112 is exposed from the first surface 11S of the first substrate 11. The first frame 11F may at least partially surround the first electrode 112.

In some embodiments, the acoustic wave device 13 may further include a second substrate 12. The second substrate 12 includes a second bulk plate 12BP and a recess 12R. The recess 12R may be disposed in the second bulk plate 12BP and recessed from the second surface 12S of the second substrate 12. In some embodiments, the second substrate 12 of the acoustic wave device 13 may further include a second frame 12F disposed in the second bulkplate 12BP. The second frame 12F may be formed by adjusting Step 912 as needed. In some embodiments, the second substrate 12 may further include a second frame recess 12FR used for forming the second frame 12F.

In some embodiments, the first surface 11S of the first substrate 11 and the second surface 12S of the second substrate 12 are bonded together, such that when viewed along the vertical direction, the recess 12R, first electrode 112, piezoelectric layer 113, and second electrode 114 at least partially overlap to form an overlapping area OS. The first substrate 11 and the second substrate 12 form a sealed cavity at the recess 12R, with the second frame 12F at least partially surrounding the sealed cavity.

Compared to the method 200, the method 900 omits the first electrode recess 112R and/or the first frame recess 11FR. In other words, in the method 900, the first substrate 11 is not etched. The first electrode 112 and/or the first frame 11F are formed directly on the first bulk plate 11BP. The step of forming the first electrode 112 and/or the first frame 11F on the first bulk plate 11BP may include depositing a conductive layer on a surface of the first substrate 11, and then patterning the conductive layer. In some embodiments, the first electrode 112 and the first frame 11F may be formed simultaneously.

At least one embodiment of the present invention may provide an acoustic wave device and a fabrication method thereof. In an acoustic wave device, a sealed cavity is formed without the need of a through hole, so as to achieve an enhanced transmission efficiency and structural strength. Additionally, the acoustic wave device and the method according to one embodiment may include forming a frame structure at least partially surrounding the active area, so as to reduce or prevent acoustic wave leakage along the horizontal direction, thereby suppressing a spurious mode.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of fabricating an acoustic wave device, the method comprising:
providing a first substrate, the first substrate comprising a first bulkplate, a first frame, and further comprising a first electrode, a piezoelectric layer, and a second electrode stacked in sequence, wherein the first frame is disposed on the first bulkplate and at least partially surrounds the first electrode;
thinning the first substrate such that the first electrode is exposed from a first surface of the first substrate;
providing a second substrate, the second substrate comprising a second bulkplate and a recess, the recess being recessed from a second surface of the second substrate; and
bonding the first surface of the first substrate and the second surface of the second substrate together, such that the recess, the first electrode, the piezoelectric layer, and the second electrode at least partially overlap when viewed along a vertical direction to form an overlapping area.

2. The method of claim 1, wherein the step of providing the first substrate comprises:
providing the first bulkplate;
forming a first electrode recess in the first bulkplate;
forming a first frame recess in the first bulkplate, wherein the first frame recess is separated from the first electrode recess;
forming the first electrode in the first electrode recess;
forming the first frame by utilizing the first frame recess;
forming the piezoelectric layer on the first electrode; and
forming the second electrode on the piezoelectric layer.

3. The method of claim 2, wherein the step of forming the first frame by utilizing the first frame recess comprises filling the first frame recess with a conductive material or a dielectric material.

4. The method of claim 2, wherein the step of providing the first substrate further comprises:
forming a contact hole penetrating the piezoelectric layer;
forming a first contact in the contact hole, the first contact being electrically connected to the first electrode; and
forming a passivation layer to at least cover the second electrode.

5. The method of claim 4, wherein the step of thinning the first substrate comprises:
applying an adhesion layer to a first side of the first substrate;
attaching the first substrate to a carrier via the adhesion layer; and
performing a planarization process from a second side of the first substrate to reduce a thickness of the first substrate to the first surface.

6. The method of claim 5 wherein the step of bonding the first surface of the first substrate and the second surface of the second substrate together comprises:
flipping the second substrate or the first substrate, such that the second surface of the second substrate and the first surface of the first substrate are bonded; and
removing the carrier and the adhesion layer.

7. The method of claim 2, wherein the first electrode recess has a first depth, the first frame recess has a second depth, and the second depth is equal to or less than the first depth.

8. The method of claim 7, wherein thinning the first substrate such that the first frame is either exposed or not exposed from the first surface.

9. The method of claim 1, wherein the step of providing the second substrate comprises:
providing the second bulkplate; and
forming the recess in the second bulkplate.

10. The method of claim 9, wherein the step of providing the second substrate further comprises:
forming a second frame recess in the second bulkplate, wherein the second frame recess is separated from the recess.

11. The method of claim 10, wherein the recess has a third depth, the second frame recess has a fourth depth, and the fourth depth is equal to or greater than the third depth.

12. The method of claim 10, wherein the step of providing the second substrate further comprises:
filling the second frame recess with a conductive material or a dielectric material.

13. The method of claim 10, wherein the first surface of the first substrate and the second surface of the second substrate are bonded together such that a sealed cavity enclosed by the first substrate and the second substrate is formed at the recess.

14. The method of claim 13, wherein the first surface of the first substrate and the second surface of the second substrate are bonded together such that a second frame is formed by utilizing the second frame recess, wherein the second frame is disposed in the second bulkplate and the second frame at least partially surrounds the sealed cavity.

15. The method of claim 14, wherein the first frame and the second frame are at least partially aligned.

16. The method of claim 14, wherein the step of providing the second substrate further comprises:
forming a fourth frame recess in the second bulkplate, wherein the fourth frame recess is separated from the recess and separated from the second frame recess;
wherein the first surface of the first substrate and the second surface of the second substrate are bonded together such that a fourth frame is formed by utilizing the fourth frame recess, wherein the fourth frame is disposed in the second bulkplate and the fourth frame at least partially surrounds the sealed cavity; and
a horizontal distance between the fourth frame and the overlapping area is greater than a horizontal distance between the second frame and the overlapping area.

17. The method of claim 1, wherein the first substrate further comprises a third frame,
wherein the third frame is disposed in the first bulkplate and at least partially surrounds the first electrode, and
wherein a horizontal distance between the third frame and the overlapping area is greater than a horizontal distance between the first frame and the overlapping area.

18. An acoustic wave device comprising:
a first substrate comprising:
a first surface;
a first bulkplate;
a first electrode, a piezoelectric layer, and a second electrode, wherein the first electrode, the piezoelectric layer, and the second electrode are stacked in sequence, and the first electrode is exposed from the first surface; and
a first frame disposed in the first bulkplate and at least partially surrounding the first electrode; and
a second substrate comprising:
a second surface;
a second bulkplate; and
a recess disposed in the second bulkplate and recessed from the second surface;
wherein the first surface of the first substrate and the second surface of the second substrate are bonded together;
wherein the recess, the first electrode, the piezoelectric layer, and the second electrode at least partially overlap when viewed along a vertical direction; and
wherein the first substrate and the second substrate form a sealed cavity at the recess.

19. The acoustic wave device of claim 18, wherein the second substrate further comprises a second frame,
wherein the second frame is disposed in the second bulkplate and at least partially surrounds the sealed cavity.

20. The acoustic wave device of claim 19, wherein the first frame and the second frame are at least partially aligned.

21. The acoustic wave device of claim 19, wherein the first substrate further comprises a third frame,
wherein the third frame is disposed in the first bulkplate and at least partially surrounds the first electrode, and
wherein a horizontal distance between the third frame and the overlapping area is greater than a horizontal distance between the first frame and the overlapping area.

22. The acoustic wave device of claim 21, wherein the second substrate further comprises a fourth frame,
wherein the fourth frame is disposed in the second bulkplate and at least partially surrounds the sealed cavity, and a horizontal distance between the fourth frame and the overlapping area is greater than a horizontal distance between the second frame and the overlapping area.

23. The acoustic wave device of claim 22, wherein at least one of the first frame, the second frame, the third frame, and the fourth frame comprises a filling material, and the filling material comprises a conductive material or a dielectric material.

24. A method of fabricating an acoustic wave device, the method comprising:
providing a first bulkplate;
forming a first electrode on the first bulkplate;
forming a first frame on the first bulkplate, wherein the first frame at least partially surrounds the first electrode and is separated from the first electrode;
forming a piezoelectric layer at least on the first electrode;
forming a second electrode at least on the piezoelectric layer;
forming a contact hole penetrating the piezoelectric layer;
forming a first contact in the contact hole, the first contact being electrically connected to the first electrode;
forming a passivation layer to at least cover the second electrode, so as to form a first substrate;
applying an adhesion layer to a first side of the first substrate;
attaching the first substrate to a carrier via the adhesion layer;
performing a planarization process from a second side of the first substrate to reduce a thickness of the first substrate to a first surface, such that the first electrode is exposed from the first surface;
providing a second substrate, the second substrate comprising a second bulkplate and a recess, the recess being recessed from a second surface of the second substrate;
bonding the first surface of the first substrate and the second surface of the second substrate together, such that the recess, the first electrode, the piezoelectric layer, and the second electrode at least partially overlap when viewed along a vertical direction to form an overlapping area; and
removing the carrier and the adhesion layer.

25. An acoustic wave device comprising:
a first substrate comprising:
a first surface;
a first electrode, a piezoelectric layer, and a second electrode, wherein the first electrode, the piezoelectric layer, and the second electrode are stacked in sequence, and the first electrode is exposed from the first surface; and
a first frame at least partially surrounding the first electrode; and
a second substrate comprising:
a second surface;
a second bulkplate;
a recess disposed in the second bulkplate and recessed from the second surface; and
a second frame disposed in the second bulkplate;
wherein the first surface of the first substrate and the second surface of the second substrate are bonded together;
the recess, the first electrode, the piezoelectric layer, and the second electrode at least partially overlap when viewed along a vertical direction;
the first substrate and the second substrate form a sealed cavity at the recess; and
the second frame at least partially surrounds the sealed cavity.
